(19) United States
(12) Patent Application Publication
(10) Pub. No.: US 2001/0028109 A1
(43) Pub. Date: Oct. 11, 2001

(54) Solder alloy, a circuit substrate, a semiconductor device and a method of manufacturing the same

(76) Inventors: Kozo Shimizu, Kawasaki (JP); Masayuki Ochiai, Kawasaki (JP); Yasuo Yamagishi, Kawasaki (JP)

Correspondence Address: ARMSTRONG,WESTERMAN, HATTORI, McLELAND & NAUGHTON, Suite 1000, 1725 K Street, N.W., Washington, DC, 20006, US

(21) Appl. No.: 09/731,726

(22) Filed: Dec. 8, 2000

(30) Foreign Application Priority Data
Feb. 22, 2000 (JP) 2000-044827

(51) Int. Cl. H01L 23/48; H01L 23/52; H01L 29/40

(52) U.S. Cl. 257/737

(57) ABSTRACT

The main subject of the present invention is a semiconductor device with a semiconductor element bonded on a circuit substrate by a bump comprising a solder alloy. Here, the solder alloy is an Sn—Ag-based alloy having a 90 (wt %) or more Sn content, a 0.01 or less (cph/cm²) α ray amount in Sn, and a 1.5 (wt %) to 2.8 (wt %) Ag content. Accordingly, a solder alloy capable of preventing generation of a needle-like projection generated in a solder alloy at the time of bonding a semiconductor element on a circuit substrate for coping with frequent generation of a soft error accompanying the fine pitch, in executing the flip-chip bonding in a Pb-free solder alloy mainly containing Sn, with a long fatigue life without causing deterioration of the insulation resistance, and without generation of a soft error by α rays, and a semiconductor device using the same are realized.

### BACKGROUND OF THE INVENTION

1. Field of the Invention

The present invention relates to a solder alloy, a circuit substrate provided by flip-flop packaging of a bear chip of a semiconductor element using the solder alloy, a semiconductor device, and a method of manufacturing the same.

2. Description of the Related Art

Recently, with the trend of a higher density packaging in electronic parts, a larger number of input and output terminals and a more minute pitch between terminals have been adopted. As a bonding method for a semiconductor element and a substrate, a flip chip bonding method with an extremely short wiring length, capable of lump bonding has been the mainstream instead of a wire bonding method.

In the flip chip bonding, a semiconductor element and a substrate are bonded directly through a solder bump. In this case, as a solder material to be used for bonding, a Pb—Sn-based alloy has often been used so far.

However, there are a plurality of isotopes of Pb, and the isotopes are an intermediate product or a final product in the decay series of uranium (U) and thorium (Th). Since the decay series accompanies the α decay of discharging a He atom, α rays are generated from Pb in the solder. It is recently reported that the α rays reaching a semiconductor element (for example, a CMOS element) generates a soft error. Moreover, it is known that Pb discharged into the soil becomes acidic and is eluted out so as to cause the adverse effect to the environment. Also from the aspect of the environmental conservation, a solder material not using Pb is strongly called for.

Therefore, use of a solder material containing Sn as the main component, which has a relatively small amount of radioactive impurities has been started as a solder material in place of Pb-based solder material.

As a solder material containing Sn as the main component, in particular, that having an eutectic composition with Sn-3.5% Ag, and a 221° C. melting point has commonly been used recently since it has a relatively close melting point to the Sn—Pb eutectic solder (melting point: 183° C.). The solder material has a high reaction speed (dispersing property) with respect to an electrode material or Cu, and thus involves a problem of generation of defects such as bump chipping in an electrode film configuration provided in an ordinary semiconductor element or a circuit substrate. However, by skillfully arranging the electrode film configuration, the film thickness, the film formation conditions, or the like, it has been gaining the reliability.

However, although the Sn—Ag-based solder material has an advantage of including an extremely small amount of radioactive impurities hazardous in various aspects, it involves the below-mentioned problem. The problem is closely related to the circumstances of progress toward the higher integration of a semiconductor element according to the recent demand for a smaller size of a semiconductor device.

It is observed and confirmed by an optical microscope that a needle-like projection as shown in FIG. 7 is generated in the Sn—Ag-based solder alloy during the soldering process. Since the maximum length of the needle-like projection can be 200 to 300 μm, in the case the needle-like projection is generated in a minute solder bonding portion with a 200 μm or less pitch size, contact with an adjacent solder bump, generation of an ion migration with the projection as the starting point, or the like, are brought about. As a result, a defect of short circuit, or the like is generated so as to deteriorate the bonding reliability, and thus it is problematic.

Furthermore, according to a high integration of a semiconductor element, the demanded specification toward the α rays in the material becomes more and more severe for preventing the soft error generation by the α rays so that the Sn with a low α ray amount needs to be used. In this case, since the Sn with a low α ray amount is highly pure with little impurities, there are a small number of coagulation cores in the process of melting and coagulating the solder alloy. Therefore, the crystal growth is generated with the surrounding molten liquid of the alloy having adhered to the small number of the cores. As a result, in comparison with a low purity Sn, a large needle-like projection tends to be generated frequently.

In contrast, in the case of using a low purity Sn, there are a large number of coagulation cores so that the molten liquid of the alloy adheres to the cores. However, since the basic number of cores is large, they remain in a relatively minute grain size without growing drastically.

### SUMMARY OF THE INVENTION

Accordingly, in view of the above-mentioned problems, an object of the present invention is to provide a solder alloy capable of preventing generation of a needle-like projection generated in a solder alloy at the time of bonding a semiconductor element on a circuit substrate for coping with frequent generation of a soft error accompanying the fine pitch, in executing the flip-chip bonding in a Pb-free solder alloy mainly containing Sn, with a long fatigue life without causing deterioration of the insulation resistance, and without generation of a soft error by α rays, a circuit substrate using the same, a semiconductor device, and a method of manufacturing the same.

As a result of the elaborate discussion, the present inventor achieved the below-mentioned embodiments of the present invention.

The first aspect is related to a solder alloy as an Sn—Ag alloy. The solder alloy has a 90 (wt %) or more Sn content, a 0.01 or less (cph/cm²) α ray amount in the Sn, and a 1.5 (wt %) to 2.8 (wt %) Ag content.

The second aspect is a semiconductor device with a semiconductor element bonded on a circuit substrate, using the solder alloy according to the first aspect.

Here, it is preferable that the solder alloy has a composition with at least one selected from the group consisting of Cu, Zn, In, Sb, and Bi contained as an additive element.

It is further preferable that the semiconductor element and the circuit substrate are bonded among terminals of the bump at 1,000 or more positions.

The third aspect is a circuit substrate with a plurality of semiconductor elements each bonded by a bump comprising a solder alloy having a 90 (wt %) or more Sn content, a 0.01 or less (cph/cm²) α ray amount in the Sn, and a 1.5 (wt %) to 2.8 (wt %) Ag content.

The fourth aspect is a method of manufacturing for a semiconductor device with a semiconductor element bonded on a circuit substrate, using the solder alloy according to the first aspect.

In the present invention, the below-mentioned effects can be expected by limiting the Ag composition in a 1.5 (wt %) to 2.8 (wt %) low concentration with the premise that the α ray amount in the Sn is 0.01 or less (cph/cm²) in the solder alloy as the Sn—Ag-based alloy with a 90 (wt %) or more Sn content.

In the case of containing Sn as the main component in an Sn—Ag-based (in particular, alloy in the vicinity of the Sn-3.5(wt %)Ag) alloy, (see FIG. 1), it comprises two phases of Sn and Ag₃Sn during melting. The needle-like projection easily generated in the Sn—Ag based alloy is found to be Ag₃Sn₅ from the result of the analysis such as the X-ray diffraction. From this, it is presumed that the Ag₃Sn is gradually precipitated at the time of transition of the solder alloy from the liquid phase to the solid phase in the case the Ag weight ratio is larger than 3.5 (wt %). Therefore, by the crystal growth thereof, a projection larger than the bump diameter of the solder alloy is generated.

By reducing the Ag composition from 3.5 (wt %), it can exist in the liquid phase state with Sn in the solid and liquid mixed state so that the Sn phase and Ag₃Sn are coagulated and precipitated at the same time according to the temperature decline of the solder alloy. In the cooling process, since the existence ratio of the relatively large Ag₃Sn₅ to be the cores of the crystal growth is apparently lower than the case of the eutectic composition (3.5 (wt %) Ag) or more, it is learned that the probability of the needle-like projection growth is extremely small.

Based on the above-mentioned result, a concrete appropriate range of the Ag composition is considered.

At the time of bonding with an Sn—Ag-based solder alloy, Sn reacts with Au, Ni and Cu, or the like in the electrode material so as to form a metal compound (see FIG. 2) so that the Sn component in the solder alloy is reduced. According to the probability calculation of the reduction amount (see FIG. 3), it is 2.8 (wt %). In view of the above-mentioned result, it is reasonable to have this value as the appropriate Ag composition upper limit value.

Moreover, as to the lower limit value of Ag, in the case the Ag composition ratio is 1.5 (wt %) or more, in order to prevent transformation from β-Sn to α-Sn (tin pest) possibly generated at a 13° C. or less temperature in an Sn single phase, the Ag content needs to be 1.5 (wt %) or more (see Tables 1, 2), and thus it is reasonable to have this value as the appropriate Ag composition lower limit value.

In consideration of the demand for reduction of the α ray amount in Sn, for example, in the case of having the gate length of a transistor at 0.2 (μm) or less, the α ray amount needs to be 0.01 (cph/cm²) or less. If the Ag content is, for example, 3.5 (wt %), the needle-like projection is generated by lowering the α ray amount, but by having the Ag content in the above-mentioned range, generation of the projection can be restrained (see Tables 1, 2).

From the result of the above-mentioned discussion, by having the Sn, Ag contents and the α ray amount in Sn in the above-mentioned appropriate values, generation of the needle-like projection in the solder alloy can be prevented at the time of bonding a semiconductor element on a circuit substrate so that a solder alloy with a long fatigue life without deteriorating the insulation resistance, without generation of a soft error by α rays can be realized.

According to a solder alloy of the present invention, it is possible to comprise a solder material mainly containing Sn for the Pb-free configuration, prevent generation of a needle-like projection easily generated in a bump, and restrain generation of α rays.

Moreover, in the flip-chip bonding using the solder alloy, coping with frequent generation of a soft error accompanying the fine pitch, generation of a needle-like projection easily generated in a bump can be prevented so that a semiconductor device with a long fatigue life without deteriorating the insulation resistance, without generation of a soft error by α rays can be realized.

### BRIEF DESCRIPTION OF THE DRAWINGS

FIG. 1 is a graph showing the state of an Sn—Ag-based alloy;

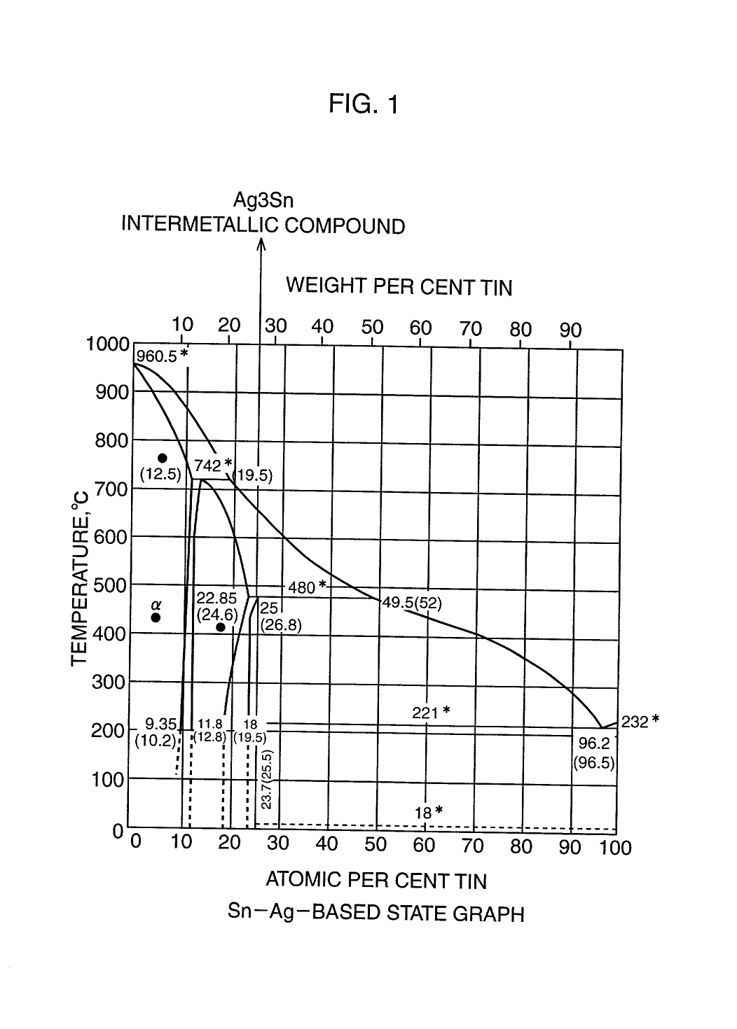

FIG. 2 is a microscope photograph of a metal compound formed by the reaction of an electrode material with Sn in a solder alloy at the interface;

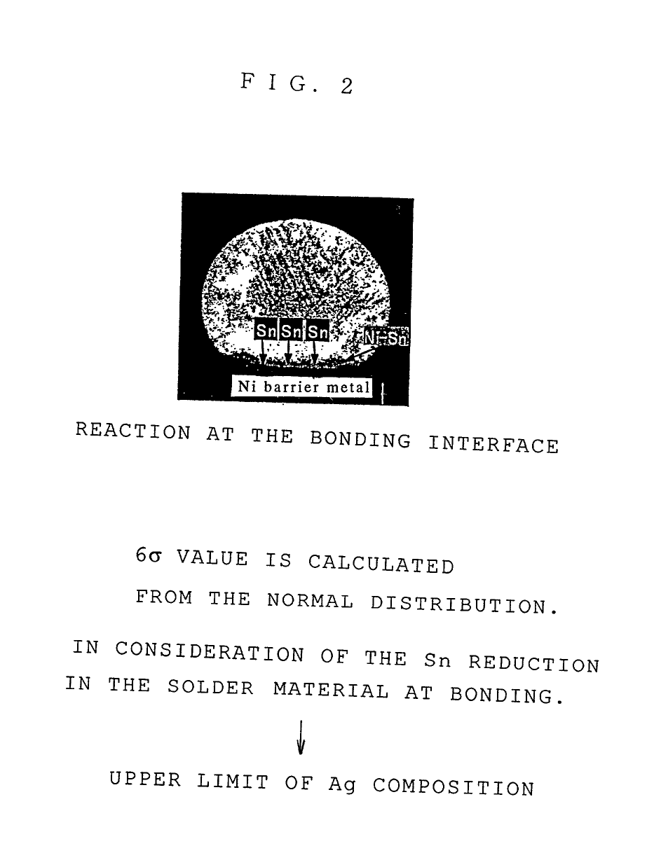

FIG. 3 is a graph showing the relationship between the Ag content and the needle-like projection generation ratio in an Sn—Ag-based solder alloy;

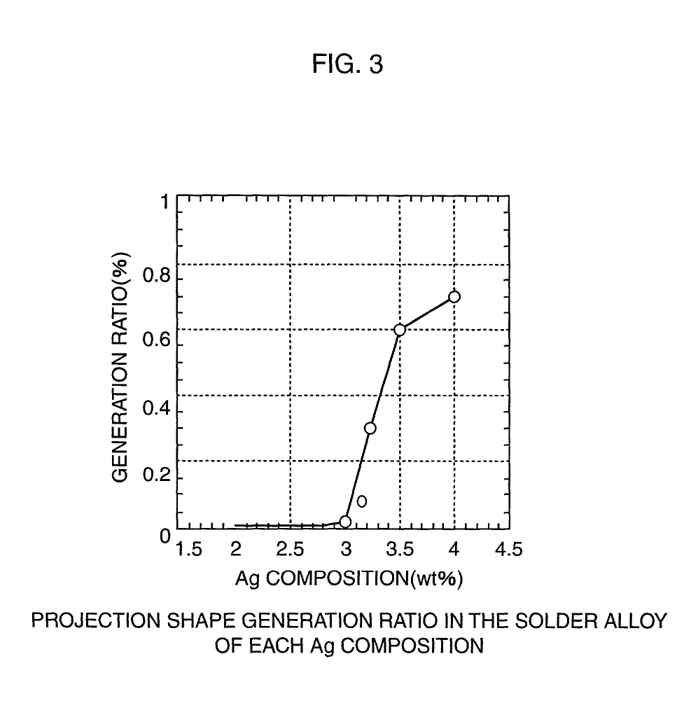

FIGS. 4A to 4G are schematic cross-sectional views showing the order of steps of a method of manufacturing for a semiconductor device according to a flip-chip bonding method of an embodiment of the present invention;

FIG. 5 is an enlarged schematic cross-sectional view of the vicinity of a formed solder bump.

FIG. 6 is a graph showing the measurement result of the relationship between the α ray amount and the soft error generation ratio in Sn in the Sn—Ag-based solder alloy.

FIG. 7 is a microscope photograph showing a needle-like projection generated in an Sn—Ag-based solder alloy.

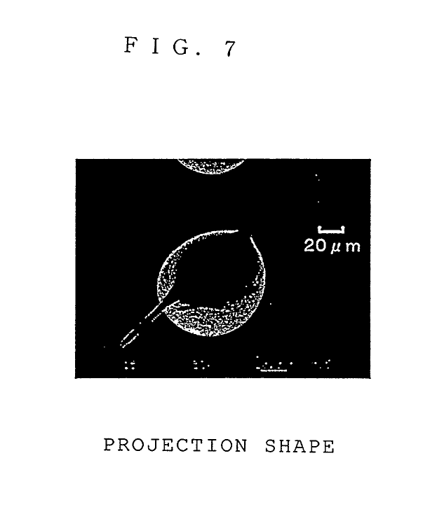

### DETAILED DESCRIPTION OF THE PREFERRED EMBODIMENT

Hereinafter, a preferable embodiment of the present invention will be explained in detail with reference to drawings.

In an embodiment of the present invention, a semiconductor device (circuit substrate) formed by the flip-chip bonding method using a solder alloy of the present invention will be described with a method of manufacturing the same.

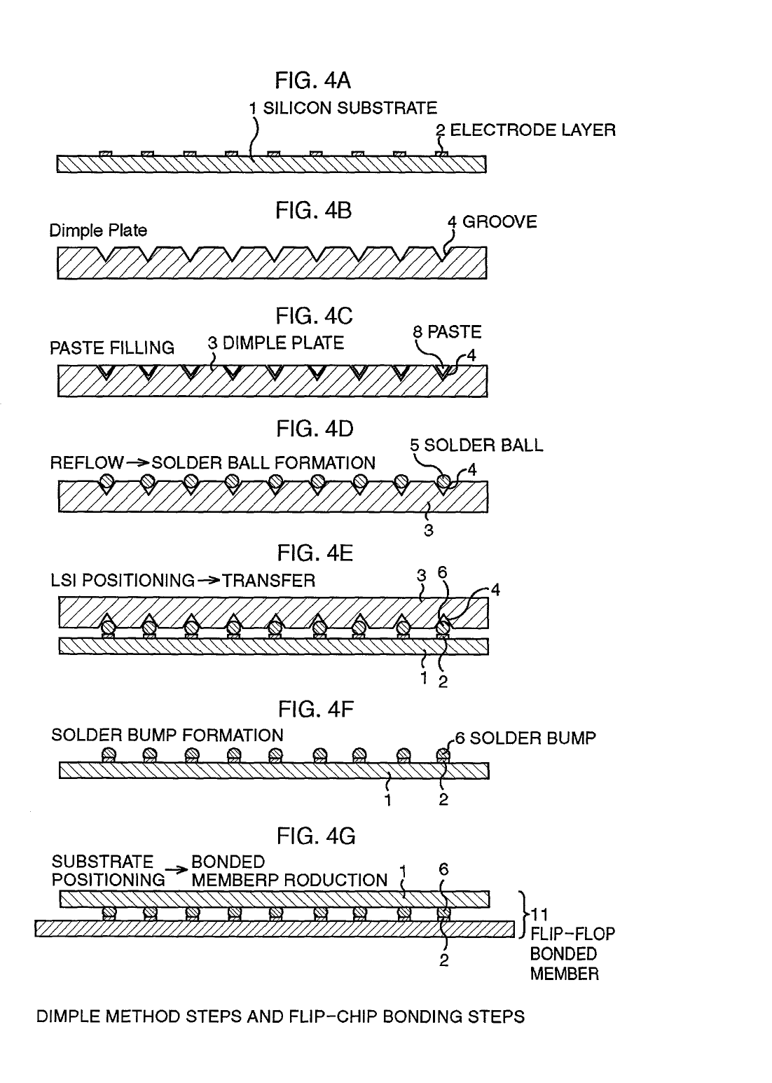

FIGS. 4A to 4G are schematic cross-sectional views showing the order of steps of the method of manufacturing of this embodiment. The method of manufacturing is a technique of a so-called dimple plate method.

First, as shown in FIG. 4A, on a silicon substrate 1 with desired semiconductor elements such as CMOS transistors, or the like formed on the surface, a Ti film is formed by about 0.1 (μm) thickness by a sputtering method on an Al electrode of about 0.1 (μm) film thickness of the semiconductor element, and an Ni film is formed by about 3 (μm) thickness by an electrolytic plating method successively so as to form each electrode layer 2. Here, the main subject is the case with the number of electrode layers 2 of 1,000 or more.

Next, as shown in FIG. 4B, each groove 4 is formed on the surface of the dimple plate 3, so as to correspond to each electrode layer 2 of the silicon substrate 1.

Next, as shown in FIG. 4C, each groove 4 of the dimple plate 3 is filled with a paste 8 containing solder alloy powder and flux. Here, the solder alloy is an Sn—Ag-based alloy having a 90 (wt %) or more Sn content, a 0.01 or less (cph/cm²) α ray amount in Sn, and a 1.5 (wt %) to 2.8 (wt %) Ag content. It is preferable that the solder alloy has a composition with at least one selected from the group consisting of Cu, Zn, In, Sb, and Bi contained as an additive element.

Next, as shown in FIG. 4D, the dimple plate 3 is heated at a predetermined temperature not less than the melting point of the solder alloy. At the time, the solder alloy powder in the paste 8 is melted so as to be integrated and spherical according to the function of the flux so that solder balls 5 of the solder alloy are formed in each groove 4.

Next, as shown in FIG. 4E, the dimple plate 3 is positioned with respect to the silicon substrate 1 such that the solder balls 5 correspond to the electrode layers 2 on the silicon substrate 1 so as to transfer the solder balls 5 onto the electrode layers 2.

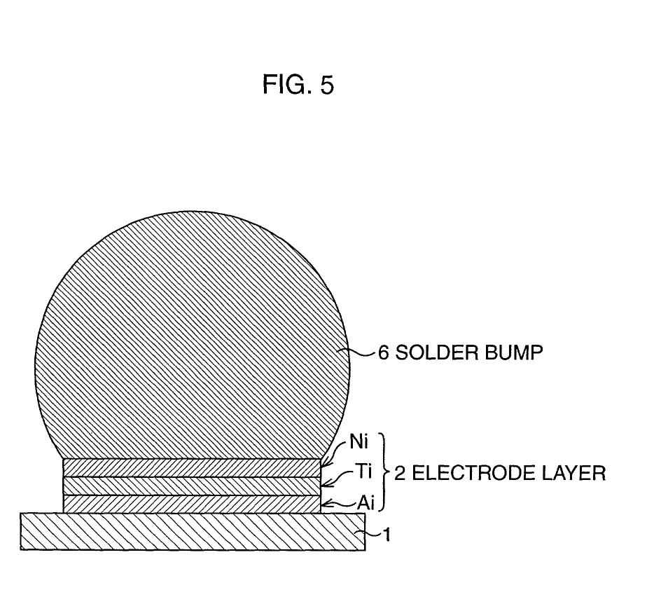

Next, as shown in FIG. 4F, by removing the dimple plate 3 from the silicon substrate 1, solder bumps 6 of the solder alloy are formed on each electrode layer 2 of the silicon substrate 1. The state of the vicinity of each solder bump 6 is shown in FIG. 5.

Next, as shown in FIG. 4G, the silicon substrate 1 is positioned with respect to a circuit substrate 7 such that the solder bumps 6 correspond to predetermined positions on the circuit substrate 7. The silicon substrate 1 and the circuit substrate 7 are bonded by the solder bumps 6 so as to produce a flip-chip bonded member 11.

Thereafter, by executing various post-treatments such as sealing of the flip-chip bonded member 11 with a resin, or the like, a semiconductor device is completed.

### EXAMPLES

Hereinafter, various functions of the solder bumps of the semiconductor device produced by the above-mentioned embodiment will be discussed in more detail.

In this example, in the solder alloy used in the manufacturing steps of FIGS. 4A to 4G (FIG. 5), generation state of the needle-like projection, the PCT, the heat cycle, the soft error generation ratio, and the transformation from βSn to αSn were examined with the Ag content, and the α ray amount in Sn each being changed.

In order to control the α ray amount in Sn, a technique of reducing the amount of the substances (mainly ²¹⁴Pb, ²¹⁰Po) related to the α ray decay series of the impurities contained in Sn is preferable. It is called, in general, a zone melt method. In this example, by a technique disclosed, for example, in the official gazette of Japanese Patent Application Laid-open (JP-A) No. 11-80852, Sn was produced, and one with the Ag added thereto was obtained with a 0.01 or less (cph/cm²) α ray amount.

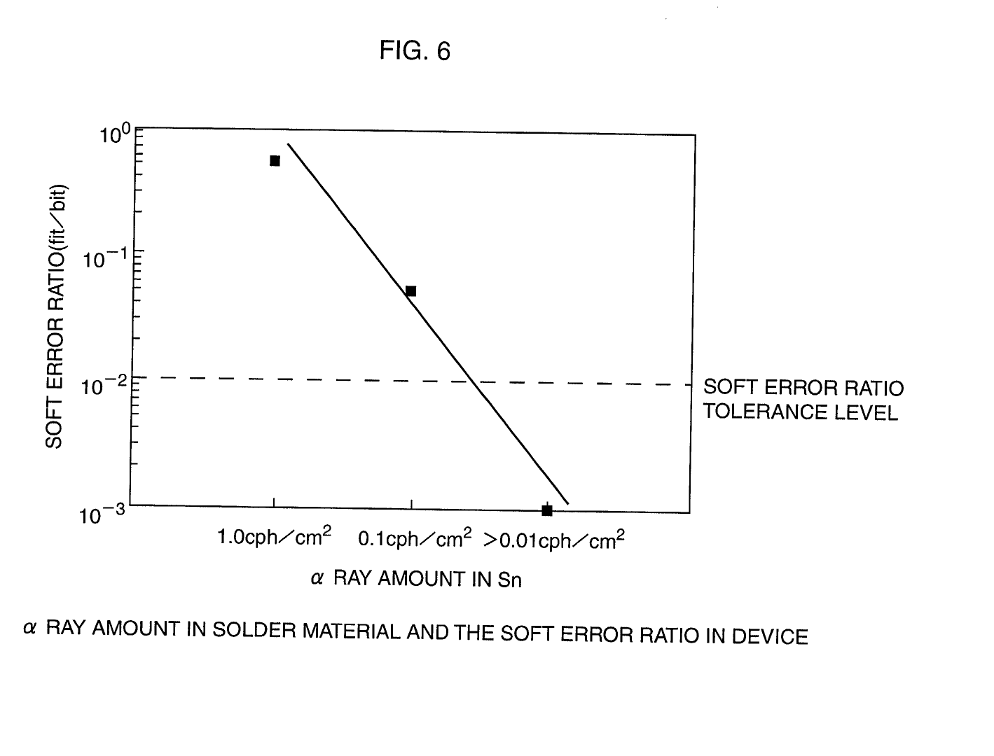

FIG. 6 shows the measurement result of the relationship between the α ray amount and the soft error generation ratio in Sn. Furthermore, Tables 1, 2 show the solder material compositions, the measurement result of the generation state of the needle-like projection, the PCT, the heat cycle test, the soft error generation ratio, or the like.

Table 1

Table 2

Here, as to the number of solder bumps 6, two kinds of silicon substrates with 2,000 bumps and 8,000 bumps were prepared. The α ray amount in Sn of the solder alloy was examined for three kinds of 1.0 (cph/cm²), 0.1 (cph/cm²), and 0.01 (cph/cm²) or less, and the Ag content in the solder alloy was examined for the range from 0.1 (wt %) to 5.0 (wt %) as shown in Table 1. Therefore, as shown in Table 1, the number of samples of silicon substrates was 25 kinds for each of 2,000 bumps and 8,000 bumps, including the solder alloys containing impurities.

For each sample, existence of needle-like crystal was observed with an optical microscope. As a result, generation of the needle-like projection observed by a 2% generation ratio (several ten pieces per one semiconductor element) in the Sn-3.5 (wt %) Ag composition was completely prevented in the 1.5 (wt %) to 2.8 (wt %) Ag composition. The projection was not generated also in each of the samples 7-4 to 7-8 with Cu, Zn, In, Bi, or Sb mixed.

Furthermore, it was also confirmed that the needle-like projection was not generated also in a high density bump packaging over 1,000 bumps.

Moreover, the relationship between the α ray amount and the generation ratio of the projection shape is also shown in Table 1.

In the Sn-3.5 (wt %) Ag composition, it is shown that the generation ratio of the projection is raised if the α ray amount in Sn is gradually reduced as 1.0→0.1→0.01 (cph/cm²). However, by having the Ag composition ratio at 2.8 (wt %) or less, the needle-like projection is not generated even in the case the α ray amount is lowered.

Actually, a flip-chip bonded member of a semiconductor element and a circuit substrate was produced according to the method of manufacturing of FIGS. 4A to 4G for executing the PCT test in the conditions of 125° C., 85% RH, and 5V application voltage. As a result, an insulation property for 100 hours or more was obtained. Moreover, as a result of the heat cycle test with the conditions of 125° C. for 30 minutes and −55° C. for 30 minutes using the same flip-chip bonded member, a sufficiently long fatigue life with 200 cycles or more was confirmed.

As heretofore explained, according to this embodiment, in flip-chip bonding with a solder alloy mainly containing Sn for Pb-freeness, a solder alloy capable of preventing generation of a needle-like projection generated in a solder alloy at the time of bonding a semiconductor element on a circuit substrate for coping with frequent generation of a soft error accompanying the fine pitch, in executing the flip-chip bonding in a Pb-free solder alloy mainly containing Sn, with a long fatigue life without causing deterioration of the insulation resistance, and without generation of a soft error by α rays, a circuit substrate using the same, a semiconductor device, and a method of manufacturing the same can be realized.

TABLE 1
NEEDLE-LIKE PROJECTION GENERATION RATIO, PCT, HEAT
CYCLE TEST, AND SOFT ERROR RATIO IN EACH ALLOY

| | | | PROJECTION | | | | | βSN→αSN |
|---|---|---|---|---|---|---|---|---|
| | | αRAY | GENERATION | | | HEAT | SOFT | NO |
| | | AMOUNT | RATIO (%) | | PCT | CYCLE | ERROR | PROBLEM: ◯ |
| Sample | ALLOY | (cph/ | 2,000 | 8,000 | TEST | TEST | RATIO | SOME |
| No. | COMPOSITION | cm²) | BUMPS | BUMPS | (TIME) | (CYCLE) | (fit/bit) | PROBLEM: X |
| 1 | Sn-0.1% Ag | 0.01< | 0 | 0 | 200 H | 200 CYCLES | 0.001< | X |
| | | | | | OR MORE | OR MORE | | |
| 2 | Sn-0.5% Ag | 0.01< | 0 | 0 | 200 H | 200 CYCLES | 0.001< | X |
| | | | | | OR MORE | OR MORE | | |
| 3 | Sn-1.0% Ag | 0.01< | 0 | 0 | 200 H | 200 CYCLES | 0.001< | x |
| | | | | | OR MORE | OR MORE | | |
| 4 | Sn-1.5% Ag | 0.01< | 0 | 0 | 200 H | 200 CYCLES | 0.001< | ◯ |
| | | | | | OR MORE | OR MORE | | |
| 5-1 | Sn-2.0% Ag | 1 | 0 | 0 | 200 H | 200 CYCLES | 0.5 | ◯ |
| | | | | | OR MORE | OR MORE | | |
| 5-2 | Sn-2.0% Ag | 0.1 | 0 | 0 | 200 H | 200 CYCLES | 0.02 | ◯ |
| | | | | | OR MORE | OR MORE | | |
| 5-3 | Sn-2.0% Ag | 0.01 < | 0 | 0 | 200 H | 200 CYCLES | 0.001 < | ◯ |
| | | | | | OR MORE | OR MORE | | |
| 6-1 | Sn-2.5% Ag | 1 | 0 | 0 | 200 H | 200 CYCLES | 0.5 | ◯ |
| | | | | | OR MORE | OR MORE | | |
| 6-2 | Sn-2.5% Ag | 0.1 | 0 | 0 | 200 H | 200 CYCLES | 0.02 | ◯ |
| | | | | | OR MORE | OR MORE | | |
| 6-3 | Sn-2.5% Ag | 0.01< | 0 | 0 | 200 H | 200 CYCLES | 0.001< | ◯ |
| | | | | | OR MORE | OR MORE | | |
| 7-1 | Sn-2.8% Ag | 1 | 0 | 0 | 200 H | 200 CYCLES | 0.5 | ◯ |
| | | | | | OR MORE | OR MORE | | |
| 7-2 | Sn-2.8% Ag | 0.1 | 0 | 0 | 200 H | 200 CYCLES | 0.02 | ◯ |
| | | | | | OR MORE | OR MORE | | |
| 7-3 | Sn-2.8% Ag | 0.01< | 0 | 0 | 200 H | 200 CYCLES | 0.001< | ◯ |
| | | | | | OR MORE | OR MORE | | |
| 7-4 | Sn- | 0.01< | 0 | 0 | 200 H | 200 CYCLES | 0.001< | ◯ |
| | 2.8% Ag- | | | | OR MORE | OR MORE | | |
| | 1.0% Zn | | | | | | | |
| 7-5 | Sn- | 0.01< | 0 | 0 | 200 H | 200 CYCLES | 0.001< | ◯ |
| | 2.8% Ag- | | | | OR MORE | OR MORE | | |
| | 1.0% Bi | | | | | | | |
| 7-6 | Sn- | 0.01< | 0 | 0 | 200 H | 200 CYCLES | 0.001< | ◯ |
| | 2.8% Ag- | | | | OR MORE | OR MORE | | |
| | 0.7% Cu | | | | | | | |
| 7-7 | Sn- | 0.01< | 0 | 0 | 200 H | 200 CYCLES | 0.001< | ◯ |
| | 2.8% Ag- | | | | OR MORE | OR MORE | | |
| | 1.0% Sb | | | | | | | |
| 7-8 | Sn- | 0.01< | 0 | 0 | 200 H | 200 CYCLES | 0.001< | ◯ |
| | 2.8% Ag- | | | | OR MORE | OR MORE | | |
| | 1.0% lu | | | | | | | |

TABLE 2
NEEDLE-LIKE PROJECTION GENERATION RATIO, PCT, HEAT
CYCLE TEST, AND SOFT ERROR RATIO IN EACH ALLOY

| | | | PROJECTION | | | | | βSN→αSN |
|---|---|---|---|---|---|---|---|---|
| | | αRAY | GENERATION | | | HEAT | SOFT | NO |
| | | AMOUNT | RATIO (%) | | PCT | CYCLE | ERROR | PROBLEM: ◯ |
| Sample | ALLOY | (cph/ | 2,000 | 8,000 | TEST | TEST | RATIO | SOME |
| No. | COMPOSITION | cm²) | BUMPS | BUMPS | (TIME) | (CYCLE) | (fit/bit) | PROBLEM: X |
| 8 | Sn-3.0% Ag | 0.01< | 0.025 | 0.05 | 50˜ | 200 CYCLES | 0.001 < | ◯ |
| | | | | | 100 | OR MORE | | |
| 9 | Sn-3.25% Ag | 0.01< | 0.3 | — | 50˜ | 200 CYCLES | 0.001< | ◯ |
| | | | | | 100 | OR MORE | | |
| 10-1 | Sn-3.5% Ag | 1 | 0.6 | — | 50˜ | 200 CYCLES | 0.5 | ◯ |
| | | | | | 100 | OR MORE | | |
| 10-2 | Sn-3.5% Ag | 0.1 | 1.0 | — | 50˜ | 200 CYCLES | 0.02 | ◯ |
| | | | | | 100 | OR MORE | | |
| 10-3 | Sn-3.5% Ag | 0.01< | 2.0 | 8.0 | 50˜ | 200 CYCLES | 0.001< | ◯ |
| | | | | | 100 | OR MORE | | |
| 11 | Sn-4.0% Ag | 0.01 < | 0.7 | — | 50˜ | 200 CYCLES | 0.001< | ◯ |
| | | | | | 100 | OR MORE | | |
| 12 | Sn-5.0% Ag | 0.01< | 3.0 | — | 50˜ | 200 CYCLES | 0.001< | ◯ |
| | | | | | 100 | OR MORE | | |

What is claimed is:

1. A semiconductor device comprising a circuit substrate, a semiconductor element, and a bump made of a solder alloy through which said semiconductor element is bonded onto said circuit substrate,
said solder alloy being an Sn—Ag-based alloy having its Sn content of 90 (wt %) or more and its Ag content within the range of 1.5 (wt %) to 2.8 (wt %), the amount of α rays in Sn being 0.01 (cph/cm²) or less.

2. The device according to claim 1, wherein said semiconductor element is connected to said circuit substrate through 1,000 or more terminals each of which is made of a bump.

3. The device according to claim 1, wherein said solder alloy contains at least one of Cu, Zn, In, Sb, and Bi as an additive ingredient.

4. A circuit substrate comprising semiconductor elements bonded thereon through bumps made of a solder alloy,
said solder alloy being an Sn—Ag-based alloy having its Sn content of 90 (wt %) or more and its Ag content within the range of 1.5 (wt %) to 2.8 (wt %), the amount of α rays in Sn being 0.01 (cph/cm²) or less.

5. The substrate according to claim 4, wherein each of said semiconductor elements is connected to said circuit substrate through 1,000 or more terminals each of which is made of a bump.

6. The substrate according to claim 4, wherein said solder alloy contains at least one of Cu, Zn, In, Sb, and Bi as an additive ingredient.

7. A manufacturing method of a semiconductor device, said method comprising the step of bonding a semiconductor element onto a circuit substrate through a bump made of a solder alloy,
said solder alloy being an Sn—Ag-based alloy having its Sn content of 90 (wt %) or more and its Ag content within the range of 1.5 (wt %) to 2.8 (wt %), the amount of α rays in Sn being 0.01 (cph/cm²) or less.

8. The method according to claim 7, wherein said semiconductor element is connected to said circuit substrate through 1,000 or more terminals each of which is made of a bump.

9. The method according to claim 7, wherein said solder alloy contains at least one of Cu, Zn, In, Sb, and Bi as an additive ingredient.

10. A manufacturing method of a semiconductor device, said method comprising the steps of:
forming electrodes on a circuit substrate;
forming grooves in a surface of a plate so as respectively to correspond to said electrodes;
filling each of said grooves with a solder alloy that is an Sn—Ag-based alloy having its Sn content of 90 (wt %) or more and its Ag content within the range of 1.5 (wt %) to 2.8 (wt %), the amount of α rays in Sn being 0.01 (cph/cm²) or less;
heating said plate to a predetermined temperature more than the melting point of said solder alloy, to form solder balls made of said solder alloy;
putting said plate on said circuit substrate such that said solder balls respectively correspond to said electrodes on said circuit substrate, and thereby transferring each of said solder balls onto the corresponding one of said electrodes; and
removing said plate.

11. The method according to claim 10, further comprising the step of connecting a semiconductor element to said circuit substrate through 1,000 or more terminals each of which is made of a solder ball.

12. The method according to claim 10, wherein said solder alloy contains at least one of Cu, Zn, In, Sb, and Bi as an additive ingredient.

13. An Sn—Ag-based solder alloy having its Sn content of 90 (wt %) or more and its Ag content within the range of 1.5 (wt %) to 2.8 (wt %), the amount of a rays in Sn being 0.01 (cph/cm²) or less.

14. The alloy according to claim 13, containing at least one of Cu, Zn, In, Sb, and Bi as an additive ingredient.
